(19) United States
(12) Patent Application Publication
(10) Pub. No.: US 2010/0006862 A1
(43) Pub. Date: Jan. 14, 2010

(54) Substrate for fabricating light emitting device and light emitting device fabricated therefrom

(75) Inventor: Chih-Ching Cheng, Taichung (TW)

Correspondence Address: BACON & THOMAS, PLLC, 625 SLATERS LANE, FOURTH FLOOR, ALEXANDRIA, VA, 22314-1176, US

(73) Assignee: HUGA OPTOTECH INC., Taichung (TW)

(21) Appl. No.: 12/453,409

(22) Filed: May 11, 2009

(30) Foreign Application Priority Data
Jul. 14, 2008 (TW) 097126565

(51) Int. Cl. H01L 33/00; B32B 3/00

(52) U.S. Cl. 257/79; 428/156

(57) ABSTRACT

The invention provides a substrate for fabricating a light emitting device and the light emitting device fabricated therefrom. The substrate includes at least one platform region having a first facet direction for epitaxial growth; and a plurality of continuous protruded portions surrounding the at least one platform region to isolate the at least one platform region from another platform region, wherein the first facet direction is substantially excluded from facet directions of the plurality of continuous protruded portions. Since facet directions of the plurality of continuous protruded portions substantially do not include the first facet direction, during formation of the light emitting device, epitaxial growth is mainly conducted on the at least one platform region, which may prevent epitaxial defects from generating and enhance external quantum efficiency of the light emitting device.

### FIELD OF THE INVENTION

The present invention relates generally to a substrate for fabricating a light emitting device and the light emitting device fabricated therefrom. More particularly, the present invention relates to a substrate for fabricating a light emitting diode (LED) and the LED with high light extraction efficiency fabricated therefrom.

### BACKGROUND OF THE INVENTION

In recent years, a light emitting device, or a light emitting diode (LED), has been widely used in the applications such as back lights of displays or lighting, since LED has certain advantages of high luminance and “environmentally friendly”. However, for one skilled in the art, it is generally known that the poor quantum efficiency (external or internal) of LED may result in transferring the energy which has not been successfully converted into light into heat, and if the heat has not been properly dissipated from LED effectively, it may subsequently result in raising the temperature of LED and reducing the light emitting efficiency.

Generally, during the epitaxial growth of LED, if the epitaxial film contains large amount of dislocation, the internal quantum efficiency will be decreased. The internal quantum efficiency is proportional to light generated from the emitting layer, and the internal quantum efficiency is up to 100% for an ideal situation. The external quantum efficiency is the ratio of light outputting LED to light generated from the emitting layer.

To effectively enhance the external quantum efficiency, it is generally known for one skilled in the art to use a patterned substrate as a substrate for epitaxial growth. With reference to FIG. 6, light generated from the emitting layer of the epitaxial film substantially propagating along the plane of the film is directed to a direction perpendicular to the plane of the film due to the total internal reflection (TIR) effect resulted from the structure of the patterned substrate, and the light extraction efficiency is thus enhanced.

However, as shown in FIGS. 5A to 5D, the patterned substrate has two surfaces (40, 40′) for growing the epitaxial film. For a hexagonal single crystal structure of a C-plane sapphire substrate, the epitaxial film is primarily grown along the Miller index (0001) facet of the C-plane sapphire substrate, and almost not grown along the other facets. Therefore, since there are two surfaces (40, 40′) for growing the epitaxial film, when the patterned substrate 41 is used to grow the epitaxial film by a lateral epitaxial growth technique, the laterally grown epitaxial film 42′ will usually be formed with interval defects 48 on top of the trench. When light travels through these interval defects with irregular shapes, light will be scattered by the defects and the total internal reflection effect will be reduced, so as to reduce the external quantum efficiency.

Besides, since the total internal reflection effect caused by the structure of the patterned substrate is increased with the increasing of the surface of the patterned substrate provided for total internal reflection, if the protruded areas are increased, for example by connecting the protruded areas to increase the effective surface areas for total internal reflection, the efficiency will also be increased.

Thus, a requirement still remains for a patterned substrate provided with one primary platform for epitaxial growth to prevent interval defects from generating and with increased effective surface areas for total internal reflection.

Solutions to these problems have been long sought but prior developments have not taught or suggested any solutions and, thus, solutions to these problems have long eluded those skilled in the art.

### SUMMARY OF THE INVENTION

An objective of the present invention is to provide a substrate for fabricating a light emitting device having an improved surface structure provided with a major growth platform to prevent interval defects from generating and having increased effective surface areas of the protruded portions for enhancing total internal reflection (TIR) effect.

The present invention provides a substrate for fabricating a light emitting device, comprising: at least one platform region having a first facet direction for epitaxial growth; and a plurality of continuous protruded portions surrounding the at least one platform region to isolate the at least one platform region from another platform region, wherein the first facet direction is substantially excluded from facet directions of the plurality of continuous protruded portions.

Preferably, the plurality of continuous protruded portions have a curved surface or a flat surface.

Preferably, the first facet direction is (0001) facet direction for C-plane sapphire.

Preferably, the substrate is formed of sapphire or a silicon-comprising material.

The present invention further provides a light emitting device, comprising: a substrate comprising at least one platform region having a first facet direction for epitaxial growth; and a plurality of continuous protruded portions surrounding the at least one platform region to isolate the at least one platform region from another platform region, the first facet direction being substantially excluded from facet directions of the plurality of continuous protruded portions; an epitaxial stacking structure provided on the substrate, sequentially comprising a first semiconductor layer, a light emitting layer, and a second semiconductor layer along a stacking direction, the first semiconductor layer comprising a first portion which is not covered by the light emitting layer and the second semiconductor layer; a first electrode engaged with the first portion of the first semiconductor layer; and a second electrode engaged with the second semiconductor layer and electrically separated from the first electrode.

Preferably, the first semiconductor layer is an n-type semiconductor and the second semiconductor layer is a p-type semiconductor.

The present invention further provides a substrate for fabricating a light emitting device, comprising: at least one platform region served as a primary platform for epitaxial growth; and a plurality of continuous protruded portions surrounding the at least one platform region to isolate the at least one platform region from another platform region so as to enhance light extraction efficiency.

The present invention further provides a light emitting device, comprising: a substrate comprising at least one platform region served as a primary platform for epitaxial growth; and a plurality of continuous protruded portions surrounding the at least one platform region to isolate the at least one platform region from another platform region so as to enhance light extraction efficiency; an epitaxial stacking structure provided on the substrate, sequentially comprising a first semiconductor layer, a light emitting layer, and a second semiconductor layer along a stacking direction, the first semiconductor layer comprising a first portion which is not covered by the light emitting layer and the second semiconductor layer; a first electrode engaged with the first portion of the first semiconductor layer; and a second electrode engaged with the second semiconductor layer and electrically separated from the first electrode.

Certain embodiments of the invention have other aspects in addition to or in place of those mentioned above. The aspects will become apparent to those skilled in the art from a reading of the following description when taken with reference to the accompanying drawings.

### BRIEF DESCRIPTION OF THE DRAWINGS

Relevant embodiments of the present invention will be described in detail below with reference to the accompanying drawings, in which:

FIG. 1A is a perspective view of a preferred embodiment of the patterned substrate of the present invention.

FIG. 1B is a sectional view along lines 1B-1B′ of FIG. 1A.

FIG. 1C is a sectional view along lines 1C-1C′ of FIG. 1A.

FIG. 2A is a perspective view of another preferred embodiment of the patterned substrate of the present invention.

FIG. 2B is a sectional view along lines 2B-2B′ of FIG. 2A.

FIG. 2C is a sectional view along lines 2C-2C′ of FIG. 2A.

FIG. 2D is a top view of FIG. 2A.

FIG. 2E is a top view of another preferred embodiment of the patterned substrate of the present invention.

FIGS. 3A to 3D are schematic diagrams showing a production flow of a preferred embodiment of the light emitting device of the present invention.

FIG. 4 is an enlarged sectional view of a preferred embodiment of the patterned substrate of the present invention.

FIGS. 5A to 5D are schematic diagrams showing a production flow of a conventional light emitting device.

FIG. 6 is a schematic diagram illustrating the optical paths of the total internal reflection (TIR) effect of a patterned substrate.

### DETAIL DESCRIPTION OF THE PREFERRED EMBODIMENT

The following embodiments are described in sufficient detail to enable those skilled in the art to make and use the invention. It is to be understood that other embodiments would be evident based on the present disclosure, and that process and mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

In the following description, several examples are given to provide a thorough understanding of the patterned substrate of the invention.

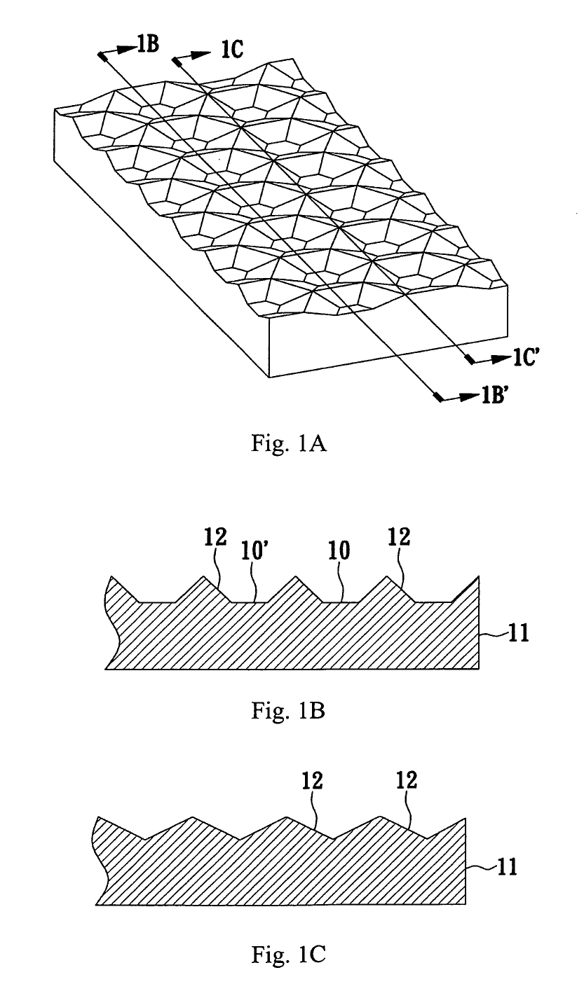

FIGS. 1A to 1C illustrate an embodiment of the patterned substrate of the invention. FIG. 1A is a perspective view of a preferred embodiment of the patterned substrate of the present invention. FIG. 1B is a sectional view along lines 1B-1B′ of FIG. 1A. FIG. 1C is a sectional view along lines 1C-1C′ of FIG. 1A.

With reference to FIG. 1A, the patterned substrate 11 for fabricating a light emitting device of the present invention comprises: at least one platform region 10 having a first facet direction for epitaxial growth, for example the (0001) facet direction of C-plane sapphire; and a plurality of continuous protruded portions 12 surrounding the at least one platform region 10 to isolate the at least one platform region 10 from another platform region 10′, wherein the first facet direction is substantially excluded from facet directions of the plurality of continuous protruded portions 12. The plurality of continuous protruded portions 12 have a flat surface.

As shown in the sectional views FIG. 1B and FIG. 1C, the patterned substrate 11 primarily has a platform region 10 for growing epitaxial film, and the epitaxial film is formed primarily along the facet (0001) of C-plane sapphire and substantially not formed on other facets. Besides, the plurality of continuous protruded portions 12 surround the at least one platform region 10 and engaged with each other, such that the effective surface areas of the patterned substrate 11 for total internal reflection are maximized and the light extraction efficiency is remarkably increased.

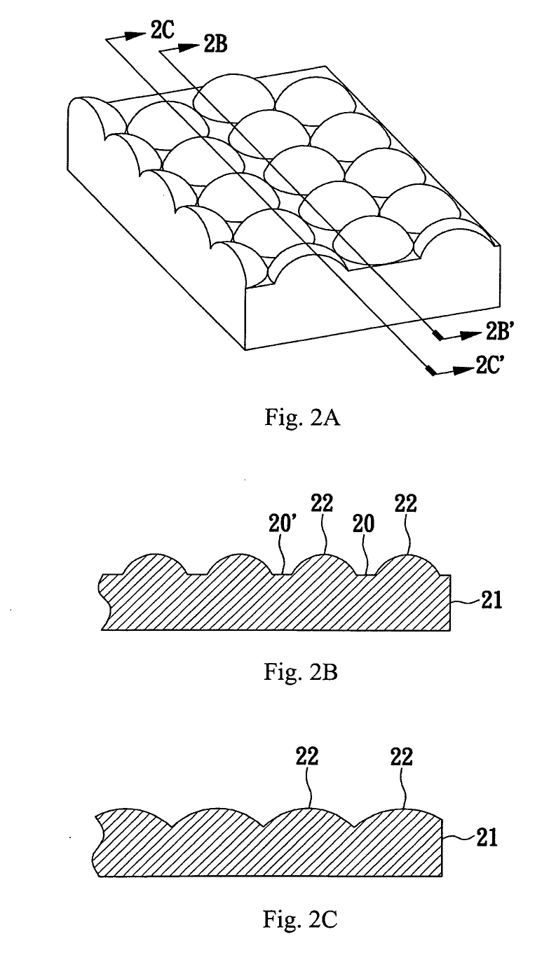

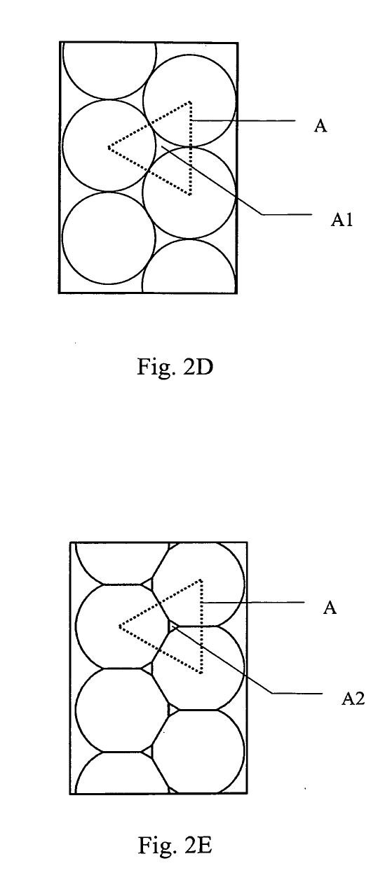

FIGS. 2A to 2C illustrate another embodiment of the patterned substrate of the invention. FIG. 2A is a perspective view of another preferred embodiment of the patterned substrate of the present invention. FIG. 2B is a sectional view along lines 2B-2B′ of FIG. 2A. FIG. 2C is a sectional view along lines 2C-2C′ of FIG. 2A.

With reference to FIG. 2A, the patterned substrate 21 for fabricating a light emitting device of the present invention comprises: at least one platform region 20 having a first facet direction for epitaxial growth, for example the (0001) facet direction of C-plane sapphire; and a plurality of continuous protruded portions 22 surrounding the at least one platform region 20 to isolate the at least one platform region 20 from another platform region 20′, wherein the first facet direction is substantially excluded from facet directions of the plurality of continuous protruded portions 22. The plurality of continuous protruded portions 22 have a curved surface.

As shown in the sectional views FIG. 2B and FIG. 2C, the patterned substrate 21 primarily has a platform region 20 for growing epitaxial film, and the epitaxial film is formed primarily along the facet (0001) of C-plane sapphire and substantially not formed on other facets. Besides, the plurality of continuous protruded portions 22 surround the at least one platform region 20 and engaged with each other, such that the effective surface areas of the patterned substrate 21 for total internal reflection are maximized and the light extraction efficiency is remarkably increased.

Further, FIGS. 2D and 2E illustrate an example of the patterned substrate of the present invention with increased protruded areas. FIG. 2D is a top view of FIG. 2A, wherein each vertex of the triangle as indicated by dotted lines is located in the center of a circle of each of the adjacent protruded portions, the area defined by the triangle as indicated by dotted lines is A, the area of the platform region is A1, and the area of the protruded portions is A-A1. FIG. 2E is a top view of another preferred embodiment of the patterned substrate of the present invention. Similarly, in FIG. 2E, each vertex of the triangle as indicated by dotted lines is located in the center of a circle of each of the adjacent protruded portions, the area defined by the triangle is represented by reference numeral A, the area of the platform region is A2, and the area of the protruded portions is A-A2. If the area defined by the triangle as indicated by dotted lines is taken as an unit area, by comparing FIG. 2D with FIG. 2E, it is obvious that the area of the protruded portions A-A2 is larger than the area of the protruded portions A-A1.

From the above description, it is understood that in the embodiment of the patterned substrate of the present invention as shown in FIG. 2E, the area of the protruded portions is increased, such that the effective area for total internal reflection is increased, which may remarkably increase the extraction efficiency of the light emitting device. Preferably, in an embodiment of the patterned substrate of the present invention, a ratio of the area of the protruded portions in the unit area is expressed by the following equation (1):

$$\frac{A - A 1}{A} \leq x < 1 \qquad ( 1 )$$

The patterned substrate of the present invention can be formed by a dry etching process or an electron beam etching process. Alternatively, the patterned substrate of the present invention can be formed by a wet etching process with over etching performed. The dry etching, electron beam etching, and wet etching processes should be apparent to those skilled in the art without further explanation.

In the following description, several examples are given to provide a thorough understanding of the process of fabricating a light emitting device by the patterned substrate of the invention.

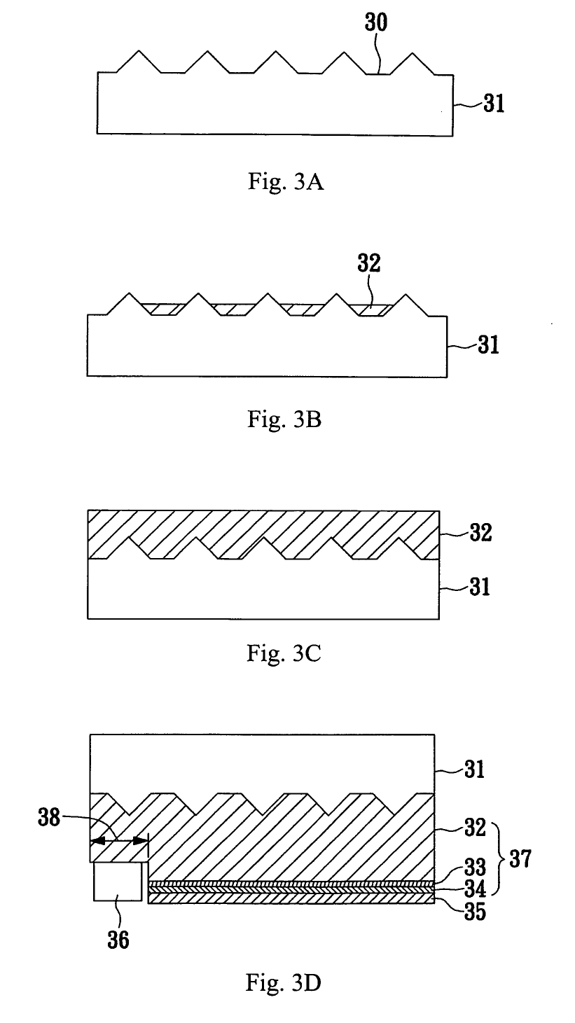

FIGS. 3A to 3D are schematic diagrams showing a production flow of a preferred embodiment of the light emitting device of the present invention. FIG. 3A shows the patterned substrate of the present invention, wherein the plurality of continuous protruded portions have a flat surface. FIG. 3B illustrates the process of forming epitaxial film on the platform region of the patterned substrate. FIG. 3C shows that the epitaxial film is formed with a thickness higher than the height of the protruded portions of the patterned substrate. FIG. 3D illustrates an embodiment of the light emitting device of the present invention, wherein the patterned substrate 31 is vertical-turned, as compared with FIG. 3C, and an epitaxial stacking structure and electrodes are further formed on the epitaxial film 32.

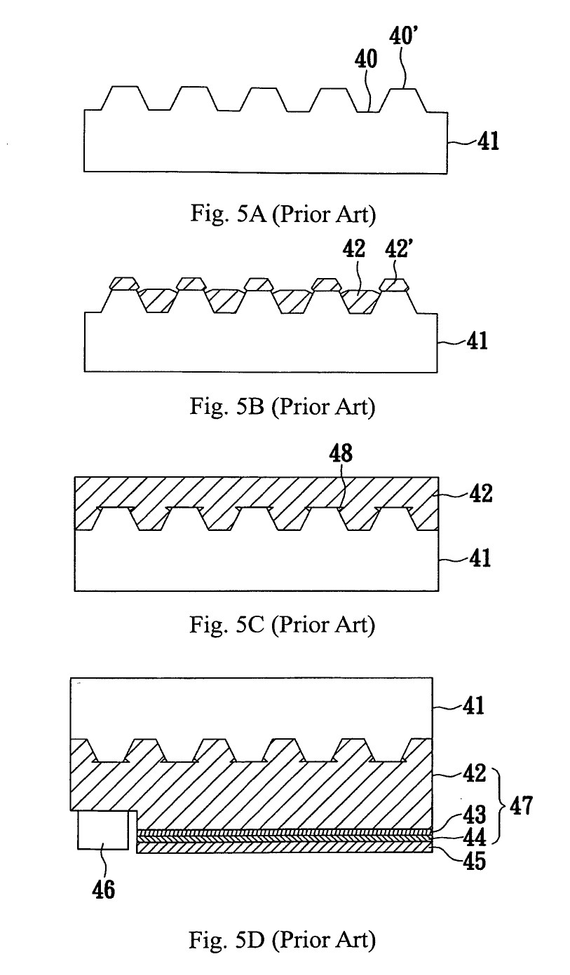

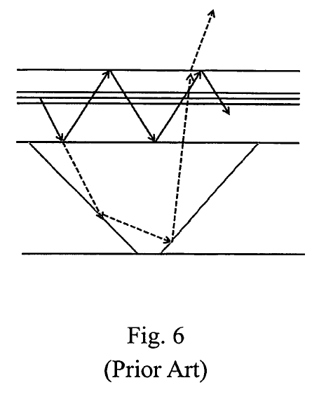

As shown in FIG. 3B, during epitaxial growth, the epitaxial film 32 is mainly formed on the at least one platform region 30 of the patterned substrate 31, which may prevent epitaxial defects as illustrated in FIG. 5B from generating.

FIG. 3D illustrates an embodiment of the light emitting device of the present invention, comprising: a substrate 31 and an epitaxial stacking structure 37 provided on the substrate 31, sequentially comprising a first semiconductor layer 32, a light emitting layer 33, and a second semiconductor layer 34 along a stacking direction, the first semiconductor layer 32 comprising a first portion 38 which is not covered by the light emitting layer 33 and the second semiconductor layer 34; a first electrode 36 engaged with the first portion 38 of the first semiconductor layer 32; and a second electrode 35 engaged with the second semiconductor layer 34 and electrically separated from the first electrode 36.

Preferably, the first semiconductor layer 32 and the second semiconductor layer 34 are formed of GaN. More preferably, the first semiconductor layer 32 is formed of an n-type GaN and the second semiconductor layer 34 is formed of a p-type GaN.

Furthermore, though the embodiment stated above is illustrated by a flip-chip packaging method, the present invention can, however, deviate from the described manner, also be packaged by other LED packaging methods such as conventional wire-bonding method, as long as the effect of increasing external quantum efficiency by the patterned substrate is achieved.

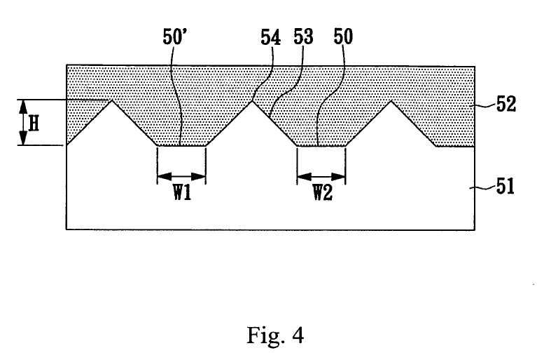

FIG. 4 further illustrates a preferred embodiment of the patterned substrate of the invention. The patterned substrate includes a platform region 50 having a first facet direction for epitaxial growth, for example the (0001) facet direction of C-plane sapphire; and a plurality of continuous protruded portions 53 surrounding the platform region 50 to isolate the platform region 50 from another platform region 50′, wherein the first facet direction is substantially excluded from facet directions of the plurality of continuous protruded portions 53. The width of the platform region 50 is W1, and the width of the platform region 50′ is W2. A distance from the platform region 50 to the highest point of the protruded portions 53 is H. In the patterned substrate of the invention, W1 and W2 may be the same or different from each other. Preferably, W1 and W2 are the same.

Further, though the examples of the patterned substrate of the invention stated above use a sapphire substrate, the present invention is not limited by these examples. Suitable substrates for growing a Group III-V semiconductor material (for example, Group III nitride semiconductor material, GaN) include but are not limited to Si, SiC, and the like.

Besides, the Group III nitride semiconductor material is not limited to GaN material. As is well understood by those in this art, the Group III elements can combine with nitrogen to form binary compounds such as AlN or InN, tertiary compounds such as AlGaN, or quaternary compounds such as AlInGaN.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. A substrate for fabricating a light emitting device, comprising:
at least one platform region having a first facet direction for epitaxial growth; and
a plurality of continuous protruded portions surrounding the at least one platform region to isolate the at least one platform region from another platform region,
wherein the first facet direction is substantially excluded from facet directions of the plurality of continuous protruded portions.

2. The substrate according to claim 1, wherein the plurality of continuous protruded portions have a curved surface.

3. The substrate according to claim 1, wherein the plurality of continuous protruded portions have a flat surface.

4. The substrate according to claim 1, wherein the first facet direction is (0001) facet direction for C-plane sapphire.

5. The substrate according to claim 1, wherein the substrate is formed of sapphire or a silicon-comprising material.

6. A light emitting device, comprising:
a substrate comprising at least one platform region having a first facet direction for epitaxial growth; and a plurality of continuous protruded portions surrounding the at least one platform region to isolate the at least one platform region from another platform region, the first facet direction being substantially excluded from facet directions of the plurality of continuous protruded portions;
an epitaxial stacking structure provided on the substrate, sequentially comprising a first semiconductor layer, a light emitting layer, and a second semiconductor layer along a stacking direction, the first semiconductor layer comprising a first portion which is not covered by the light emitting layer and the second semiconductor layer;
a first electrode engaged with the first portion of the first semiconductor layer; and
a second electrode engaged with the second semiconductor layer and electrically separated from the first electrode.

7. The light emitting device according to claim 6, wherein the first semiconductor layer is an n-type semiconductor and the second semiconductor layer is a p-type semiconductor.

8. The light emitting device according to claim 6, wherein the plurality of continuous protruded portions have a curved surface.

9. The light emitting device according to claim 6, wherein the plurality of continuous protruded portions have a flat surface.

10. The light emitting device according to claim 6, wherein the substrate is formed of sapphire or a silicon-comprising material.

11. A substrate for fabricating a light emitting device, comprising:
at least one platform region served as a primary platform for epitaxial growth; and
a plurality of continuous protruded portions surrounding the at least one platform region to isolate the at least one platform region from another platform region.

12. A light emitting device having the substrate according to claim 11, further comprising:
an epitaxial stacking structure provided on the substrate, sequentially comprising a first semiconductor layer, a light emitting layer, and a second semiconductor layer along a stacking direction, the first semiconductor layer comprising a first portion which is not covered by the light emitting layer and the second semiconductor layer;
a first electrode engaged with the first portion of the first semiconductor layer; and
a second electrode engaged with the second semiconductor layer and electrically separated from the first electrode.
